(19) United States
(12) Patent Application Publication
(10) Pub. No.: US 2001/0000160 A1
(43) Pub. Date: Apr. 5, 2001

(54) Method for treatment of semiconductor substrates

(75) Inventors: Josef Schwaiger, Teugn (DE); Gerhard Niederhofer, Neutraubling (DE); Gerhard Ott, Wernberg-Koeblitz (DE); Michael Melzl, Regensburg (DE)

Correspondence Address: WERNER H. STEMER, P.O. BOX 2480, Hollywood, FL, 33022, US

(73) Assignee: Infineon Technologies AG

(21) Appl. No.: 09/730,271

(22) Filed: Dec. 5, 2000

Related U.S. Application Data
(62) Division of application No. 09/503,664, filed on Feb. 14, 2000.

(30) Foreign Application Priority Data
Aug. 14, 1997 (DE) 197 35 399.1

(51) Int. Cl. H01L 21/31; H01L 21/469; C23C 8/00

(52) U.S. Cl. 438/783; 427/585; 438/784; 438/787

(57) ABSTRACT

A gas pipe system for a process reactor is described, which may be, for example, a vertical oven for depositing an As-doped SiO₂ layer onto wafers. The gas pipe system has a TEAS bubbler which is connected on the input side to a carrier gas source and, on the output side, is connected via at least one heated pipe to the process reactor. Furthermore, a TEOS evaporator is provided, which is connected on the input side to a gas source and, on the output side, is connected via at least one heated pipe to the process reactor. Furthermore, a vertical oven and a method for deposition of an As-doped SiO₂ layer onto wafers are described, with the gas pipe system being used in each case.

### CROSS-REFERENCE TO RELATED APPLICATION

1. This is a division of U.S. application Ser. No. 09/503,664, filed Feb. 14, 2000, which was a continuation of copending International application PCT/DE98/02352, filed Aug. 13, 1998, which designated the United States.

### BACKGROUND OF THE INVENTION

### FIELD OF THE INVENTION

2. The invention relates to a method for the treatment of semiconductor substrates, in particular for a deposition of an As-doped SiO₂ layer onto the wafers.

3. An important method in silicon technology is the CVD method (CVD=Chemical Vapor Deposition), in which gas-phase deposition can be used to produce layers such as SiO₂ layers or doped SiO₂ layers. The fundamental CVD principle consists of passing selected gases over substrates, for example wafers, located in a process reactor, with the aim of depositing a desired layer on these substrates. The process gases react on the hot substrate surface so that the reaction products are the desired layer as well as gases, which are carried out of the process reactor again.

4. It is frequently desirable for the SiO₂ layers that are produced to be doped with a further element. Such a doped layer may be produced, for example, by thermal doping. In this case, the dopant is diffused from the gas phase into the surface to be doped. Thermal doping can be carried out, for example in a CVD reactor, with the doping taking place at the same time as the SiO₂ layer deposition, that is to say doping atoms are incorporated in the SiO₂ structure.

5. One dopant that is used in practice is, for example, arsenic (As). An As-doped SiO₂ layer is produced on a substrate, for example, by thermal doping in a CVD process reactor using TEOS (tetraethylorthosilicate) and TEAS (triethylarsenate). The arsenic glass produced in this way is generally a so-called auxiliary layer, and is used as the dopant source. In a subsequent heat-treatment process, arsenic diffuses out of the arsenic glass into the silicon, where it produces an n-doped region.

6. Until now, the so-called TEAS method has been used on process reactors in the form of horizontal ovens. Such horizontal ovens contain a horizontally aligned process tube, which can be fitted with a large number of wafers. The horizontal oven is connected to a gas pipe system, via which TEOS and TEAS can pass into the process tube. However, the use of the TEAS method on horizontal ovens has a number of disadvantages.

7. For example, first of all, the accommodation capacity of a horizontal oven for the TEAS method is limited to about 100 wafers, as a result of which the method is relatively costly. Furthermore, when using the TEAS method on the horizontal ovens, differences in the layer thickness and in the arsenic content of the As-doped SiO₂ layer can occur between the individual process cycles in the oven, as a result of which the yield rate is reduced. Furthermore, there is also a risk of a relatively high particle level in the silicon layer. One reason for the disadvantages, among others, is the relatively complex gas pipe system via which TEOS and TEAS are introduced into the horizontal oven. In particular, with the known gas pipe system, it is impossible to set a TEOS/TEAS ratio defined such that stable As-doped silicon layers can be deposited.

### SUMMARY OF THE INVENTION

8. It is accordingly an object of the invention to provide a method for treatment of semiconductor substrates which overcomes the above-mentioned disadvantages of the prior art methods of this general type. In particular, the aim is to provide a method which is physically simple and by which TEAS and TEOS can be passed in a controlled manner into the process reactor such that a stable layer thickness and arsenic content can be achieved in the silicon layers, while at the same time minimizing the particle level.

9. With the foregoing and other objects in view there is provided, in accordance with the invention, a gas pipe system for treatment of semiconductor substrates, including:

10. a process reactor;

11. a carrier gas source;

12. a first evaporator for vaporizing triethylarsenate (TEAS) and having an input side connected to the carrier gas source and an output side;

13. at least one first heated pipe for connecting the output side of the first evaporator to the process reactor;

14. a gas source;

15. a second evaporator for vaporizing tetraethylorthosilicate (TEOS) and having an input side connected to the gas source and an output side; and

16. at least one second heated pipe connecting the output side of the second evaporator to the process reactor.

17. According to the invention, the object is achieved by a gas pipe system for a process reactor for the treatment of semiconductor substrates having a first evaporator for vaporizing TEAS (triethylarsenate), which is connected on the input side to a carrier gas source and, on the output side, has at least one first heated pipe for connecting the first evaporator to the process reactor. A second evaporator for vaporizing TEOS (tetraethylorthosilicate), which is connected on the input side to a gas source (26) and, on the output side, has at least one second heated pipe for connecting the second evaporator to the process reactor, is provided.

18. The process reactor is in this case preferably a horizontal or vertical oven, with the semiconductor substrates typically being wafers formed of, for example, a basic silicon substrate. The first evaporator is used to vaporize TEAS. This is preferably carried out in a so-called bubbler (apparatus for producing gas bubbles in a liquid by a carrier gas). In this case, the bubbler is connected on the input side to a carrier gas source and, on the output side, is connected via at least one first heated pipe to the process reactor. Furthermore, according to the invention, a second and so-called TEOS evaporator is provided, which is connected on the input side to a gas source and, on the output side, is connected via at least one second heated pipe to the process reactor.

19. The gas pipe system according to the invention now allows the TEAS method to be carried out in a manner suitable for production, in particular with regard to the elimination of layer thickness and particle problems, as well as problems with fluctuating arsenic content. The carrier gas source has the function of transporting the TEAS located in the TEAS bubbler (first evaporator) to the process reactor. Furthermore, the carrier gas is used as a purging and ventilating gas. The gas from the gas source that is connected to the TEOS evaporator (second evaporator) is used —as will be described further below—for filling the TEOS evaporator. The TEOS evaporator may be, according to the invention, a stainless steel source with a volume of approximately 1.2 liters. Furthermore, the TEAS bubbler may be a stainless steel source with a volume of approximately 1.5 liters, in which case the stainless steel source may contain approximately 800 g of TEAS.

20. The first evaporator (TEAS evaporator) is preferably a bubbler-type evaporator that contains liquid TEAS. In contrast, the second evaporator (TEOS evaporator) contains liquid TEOS. In the bubbler-type evaporator, also called a bubbler, a carrier gas is passed through the TEAS, and the TEAS is partially dissolved in the carrier gas, as a gas. The TEAS saturation level in the carrier gas is in this case governed on the one hand by the TEAS temperature and on the other hand by the nature of the carrier gas. Furthermore, a higher vaporization rate can be achieved by a high carrier gas flow rate through the TEAS.

21. According to the invention, a TEOS tank, that is to say a liquid tank filled with TEOS, may be disposed between the TEOS evaporator and the carrier gas source. The tank is advantageously a stainless steel tank with a capacity of approximately 14 liters.

22. In a further refinement, the TEAS source located in the TEAS bubbler may be raised via a first temperature controller to a temperature of 25 to 90° C., preferably 30 to 50° C. In this case, in order to allow the temperature to be set accurately, it may be advantageous for the temperature controller to have a regulation accuracy of ±0.5° C., at least between 25 and 90° C.

23. Furthermore, the TEOS source located in the TEOS evaporator may advantageously be raised to a temperature of 25 to 90° C., preferably 25 to 35° C., via a second temperature controller. Once again, to allow the temperature values to be set accurately, it is advantageous for the temperature controller to have an accuracy of ±0.5° C. at least between 25 and 90° C.

24. In a preferred refinement, the temperatures in the TEAS source and/or the TEOS source are kept constant. A constant temperature in the TEAS bubbler is important, for example, for the saturation level of the carrier gas. On the other hand, a constant temperature in the TEOS evaporator is important for a constant TEOS vapor pressure.

25. The correct choice of the appropriate temperatures is thus an aspect for providing a defined TEOS/TEAS ratio in the process reactor by which, inter alia, it is possible to stabilize the layer thickness and the arsenic content.

26. According to the invention, the heated pipes in the gas pipe system may have a diameter >6 mm. The diameter is preferably approximately 12 mm. The TEAS/TEOS flow can be further optimized by an appropriate choice of the diameters of the heated pipes and, in particular, by their heating. The heated pipes are advantageously drawn or electrically polished stainless steel tubes, which can be inert-gas welded orbitally.

27. In a further refinement, the (first and second) heated pipes can be heated via a pipeline heater, preferably a four-channel heater. This can be achieved, for example, by simple heating strips wound around the heated pipes.

28. In this case, it is advantageous for different temperatures to be set in different areas of the heated pipes, in which case it is possible to set a rising temperature profile from the TEAS bubbler and/or from the TEOS evaporator toward the process reactor. According to the invention, four areas of different temperature may be provided in this case in the heated pipes from the TEAS bubbler to the process reactor and/or from the TEOS evaporator to the process reactor.

29. The temperature in the different areas of the respective heated pipes is chosen so that a rising temperature profile is in each case set from the TEAS/TEOS source toward the process reactor. This prevents the formation of condensation, for example. If, for example, the temperature in the TEOS evaporator is set to an initial value of 25 to 35° C., a temperature value of 2° C. more than the initial value can be set in the first heated pipe zone, which directly follows the TEOS evaporator. In the further zones as far as the process reactor, for example in three further zones, the temperature value can then be increased by 2° C. more in each case. An identical rise in the temperature values can, for example, also be set in the different areas (zones) of the heated pipe via which the TEAS bubbler is connected to the process reactor. In this case, all that must be remembered is that the initial temperature value may be in a higher range from, for example, 30 to 50° C.

30. In a preferred refinement, at least one valve may be provided in the at least one heated pipe from the TEAS bubbler to the process reactor. Furthermore, according to the invention, at least one valve may also be provided in the at least one heatable pipe from the TEOS evaporator to the process reactor.

31. In this case, the sizes of the valves are matched to the heated pipes. The valve types used may be, for example, hand-operated valves or compressed-air-operated valves such as electropneumatic valves. However, the range of use for the gas pipe system according to the invention is not limited to these valve types. The valves are used to regulate or shut off the medium flow in individual pipes. In addition to the valves, check valves may also be provided in the gas pipe system according to the invention.

32. According to the invention, the TEAS bubbler and the carrier gas source as well as the TEOS evaporator and the gas source may each be connected via a pipe with these pipes, according to the invention, having a diameter which is less than the diameter of the heated pipes. The pipes may advantageously have a diameter of not more than 6 mm, preferably 6 mm. In this case, the pipes may be unheated. In the same way as the heated pipes, the pipes may also include drawn or electrically polished tubes, which can be inert-gas welded orbitally.

33. In a further refinement, the gas from the carrier gas source may be nitrogen (N₂). The gas from the gas source may, according to the invention, be an inert gas, preferably helium (He).

34. The gas pipe system according to the invention allows TEOS/TEAS to be supplied in an optimum manner to the process reactor. In consequence, the As-doped silicon oxide deposited on the wafers is relatively free of particles and has a good density. Furthermore, the layer thickness and the arsenic content in the deposited layers can be stabilized by the capability to adjust the TEAS/TEOS flow accurately and in a defined manner. One critical factor for this, among others, is an accurately metered TEOS/TEAS ratio that is achieved, in particular, by the heating according to the invention of individual components of the gas pipe system. Furthermore, the gas pipe system according to the invention is a physically relatively simple configuration in comparison to known gas pipe systems. In the gas pipe system according to the invention, it has been possible to minimize the gas pipe lengths and the number of gas pipes, while optimizing the gas pipe routing. In the same way, it was possible to optimize the number and installation location of the valves required, as well as the configuration of the valve controls.

35. Finally, the capability to regulate the various temperatures accurately has also been achieved. All these measures also lead to the effect that an accurately defined and finely set ratio of TEOS and TEAS can be supplied to the process reactor.

36. According to a further aspect of the invention, the gas pipe system is connected to the process reactor, with the process reactor having a process tube in which a tubular liner and a base for semiconductor substrates are disposed. A flange connected to the process tube is provided, a gas inlet and a gas outlet are provided on the process reactor, and the gas inlet is respectively connected via the first and second heated pipes to the first and second evaporators.

37. The process reactor, in particular a vertical oven for the treatment of wafers, accordingly has a process tube in which a tubular liner as well as a boot (base or holding apparatus for accommodating semiconductor substrates, in particular wafers) are provided. The flange, connected to the process tube, is used to seal the process tube. The process reactor is connected by the gas inlet to the first and second heated pipes as well as to the corresponding evaporators.

38. The use of a vertical oven for the TEAS method generally has the advantage that improved thermal screening can be achieved and the use of the tubular liner to physically separate the wafers from the gas flowing out of the oven via the gas outlet prevents any negative effect on the wafers. In particular, the configuration according to the invention allows a more stable layer thickness and a more stable arsenic content to be achieved on the wafers. The flange is advantageously detachably connected to the other components of the vertical oven. This is worthwhile since, during deposition from the gas phase, not only the substrates to be treated but also all the other elements located in the process tube as well as the inner walls of the process tube are themselves coated. These components therefore need to be replaced from time to time.

39. In an advantageous refinement, the gas inlet and/or the gas outlet are/is disposed in the flange.

40. According to the invention, the gas inlet may have a gas inlet opening for the TEOS gas supply system, and a gas inlet opening for the TEAS gas supply system.

41. In an advantageous refinement, a heating/cooling apparatus is disposed on the flange. Since the flange represents a large metallic heat sink, its heating can prevent condensation of the process gases.

42. The medium of the heating/cooling apparatus is preferably at a temperature of more than 90° C.

43. The heating/cooling apparatus for flange temperature stabilization is advantageously operated with glycol as the medium and is connected to the existing serpentine cooling coil in the flange, instead of to the cooling water supply. The aim of flange cooling/heating is to set a higher flange temperature than was normal with known methods until now, in order to avoid the above disadvantages. However, since this results in increased temperature loading on the seals, a seal material must be used which can be thermally loaded up to, for example, 250° C. Such a seal material may be, for example, TEFLON. In the situation where an oven type is used in which there is no flange cooling to which a heating/cooling apparatus can be connected, the desired effect may also be achieved by a heated flange shroud. The heating/cooling apparatus should be positioned as close as possible to the flange, in order to avoid heat losses in the pipes.

44. According to the invention, the temperature in the vertical oven may be 400 to 1250° C., preferably 600 to 700° C.

45. In a further refinement, the gas pressure inside the vertical oven may be 20 to 100 Pa, preferably 66.6±13.3 Pa (500± 100 mTorr). This gives the deposits good edge coverage.

46. The low pressure in the oven allows the concentration gradient of the reaction gases inside the oven to be kept sufficiently low that the concentration of reaction gases is virtually the same at every point on the substrate surfaces, corresponding to the gas mixture that has been set. In consequence, the pressure inside the oven can be used to further stabilize the layer thickness and the arsenic content on the individual wafers.

47. According to the invention, more than 100 wafers, preferably 150 productive wafers, may be disposed in the boot (holding apparatus). This allows considerably more wafers to be processed at the same time than in a horizontal oven, as a result of which the production costs for the individual wafers can be further reduced.

48. The vertical oven according to the invention results in that it is possible to pass TEAS/TEOS into the oven in an accurately metered and defined ratio. At the same time, disadvantageous influences resulting from the heating of the flange are avoided. Among other things, this improves the capability to use the TEAS method with a vertical oven.

49. According to a further aspect of the present invention, a method is provided for depositing an As-doped SiO₂ layer on semiconductor substrates, having the following steps:

50. fitting a process reactor, which has a process tube and a flange, with a large number of semiconductor substrates to be treated, with the semiconductor substrates being introduced into the process tube;

51. heating the process reactor to a temperature of 450 to 1250° C., preferably 600 to 700° C.;

52. heating the flange via a heating/cooling apparatus disposed on the flange, with the heating/cooling apparatus containing a medium which is at a temperature of more than 90° C.;

53. introduction of TEOS (tetraethylorthosilicate) and TEAS (triethylarsenate) into the process reactor in order to deposit the As-doped SiO₂ layer, with TEAS being introduced via at least one first heated pipe from a first evaporator which contains liquid TEAS, and TEOS being introduced via at least one second heated pipe from a second evaporator which contains liquid TEAS; and

54. depositing the As-doped SiO₂ layer on the semiconductor substrates.

55. The method according to the invention achieves the advantages, effects and influences described above with respect to the other invention aspects, with regard to the deposition of layers on the wafer surfaces.

56. In particular, TEAS is fed into the process reactor from the heated TEAS bubbler via the carrier gas—for example nitrogen—where it reacts at a raised temperature—for example at approximately 700° C.—together with the TEOS to form the As-doped silicon oxide. The reaction may take place, for example, in accordance with the following formula:

OAs (OC₂H₅)_{3 on N2}+Si(OC₂H₅)_{4 gasf}.→(AS₂O₃+SiO₂)+C₂H₄.

57. In this case, the arsenic atom is incorporated in the SiO₂ crystal.

58. A pressure of 20 to 100 Pa, preferably 66.6±13.3 Pa (500±100 mTorr), can preferably be set in the process reactor. The advantages of the specifically set pressure result from the above statements relating to the other aspects of the invention.

59. In a preferred refinement, the method can be regulated via parameters including the deposition time, temperature, pressure and the TEAS/TEOS ratio.

60. The TEOS flow can advantageously be set via the TEOS vaporization temperature. Furthermore, the TEAS flow can be set, according to the invention, via the TEAS bubbler temperature and the flow of the carrier gas. In this case, the flow of the carrier gas may advantageously be 50 to 200 standard cubic centimeters per minute (sccm).

61. In a further refinement, an As-doped SiO₂ layer with a thickness of approximately 150 nm is deposited.

62. According to the invention, the As-doped SiO₂ layer may have an arsenic content of 5.5%±2.5%.

63. Other features which are considered as characteristic for the invention are set forth in the appended claims.

64. Although the invention is illustrated and described herein as embodied in a method for treatment of semiconductor substrates, it is nevertheless not intended to be limited to the details shown, since various modifications and structural changes may be made therein without departing from the spirit of the invention and within the scope and range of equivalents of the claims.

65. The construction and method of operation of the invention, however, together with additional objects and advantages thereof will be best understood from the following description of specific embodiments when read in connection with the accompanying drawings.

### BRIEF DESCRIPTION OF THE DRAWINGS

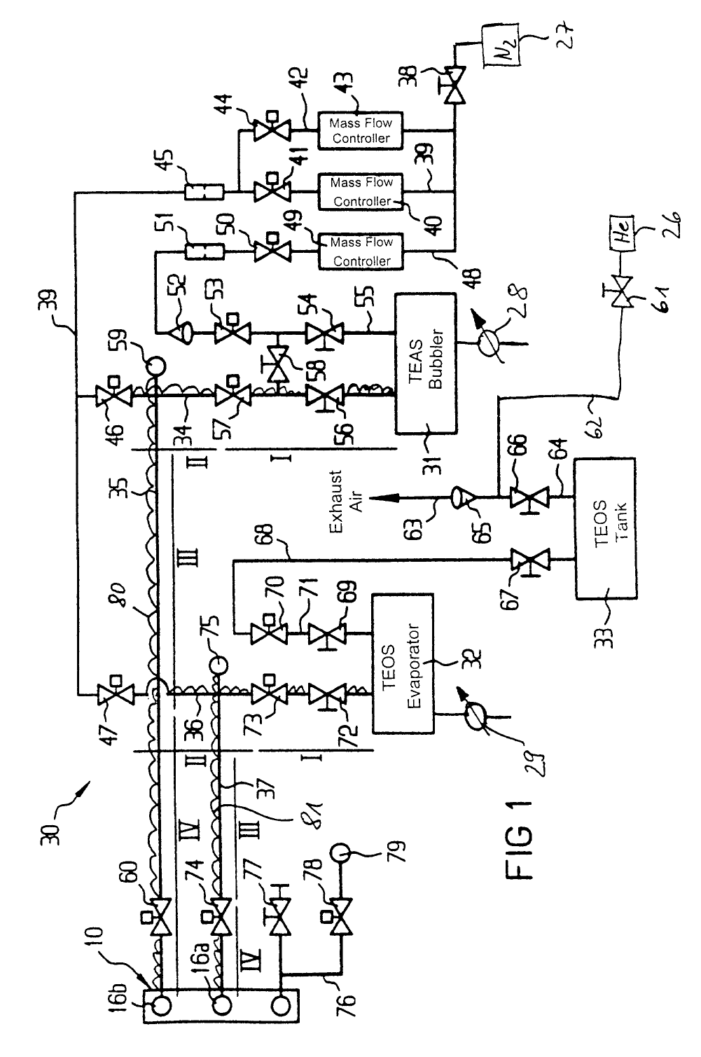

66. FIG. 1 is a diagrammatic illustration of a gas flow plan for a gas pipe system according to the invention;

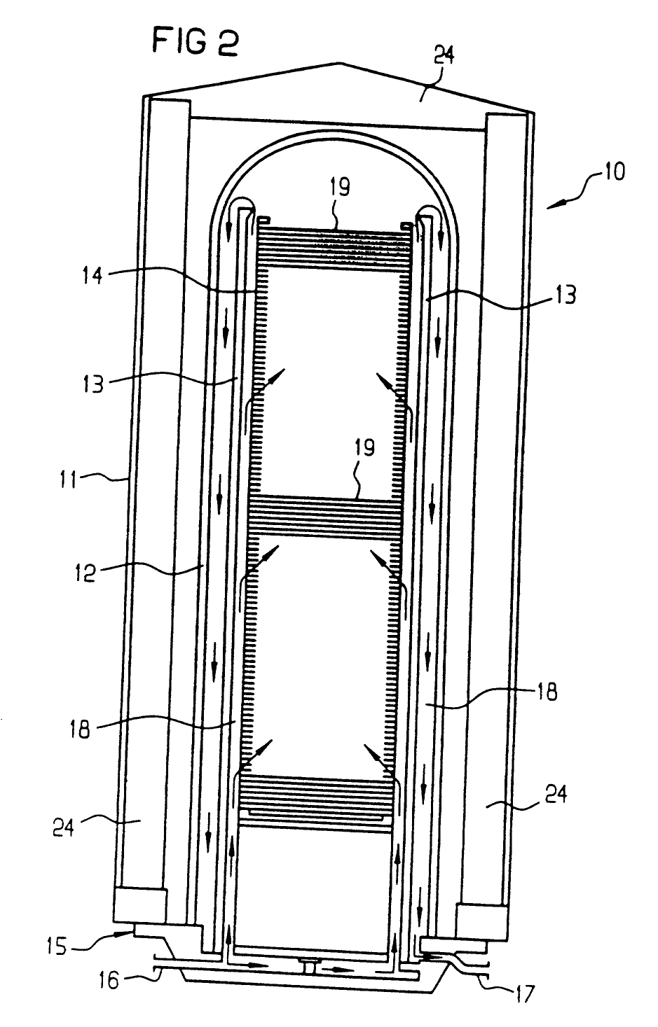

67. FIG. 2 is a cross-sectional view of a process reactor in a form of a vertical oven;

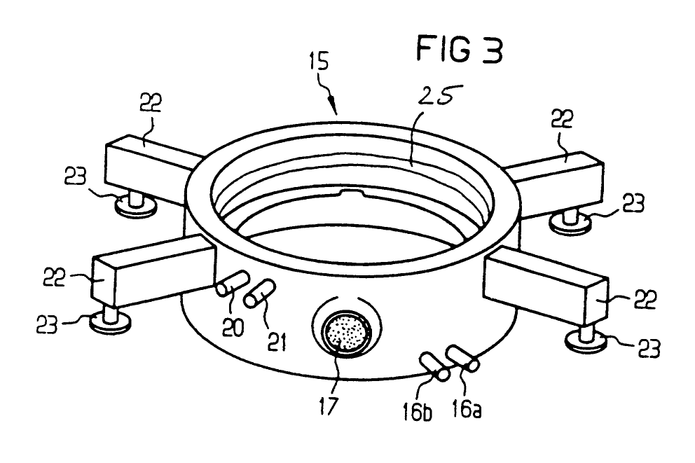

68. FIG. 3 is an enlarged perspective view of a flange of the vertical oven;

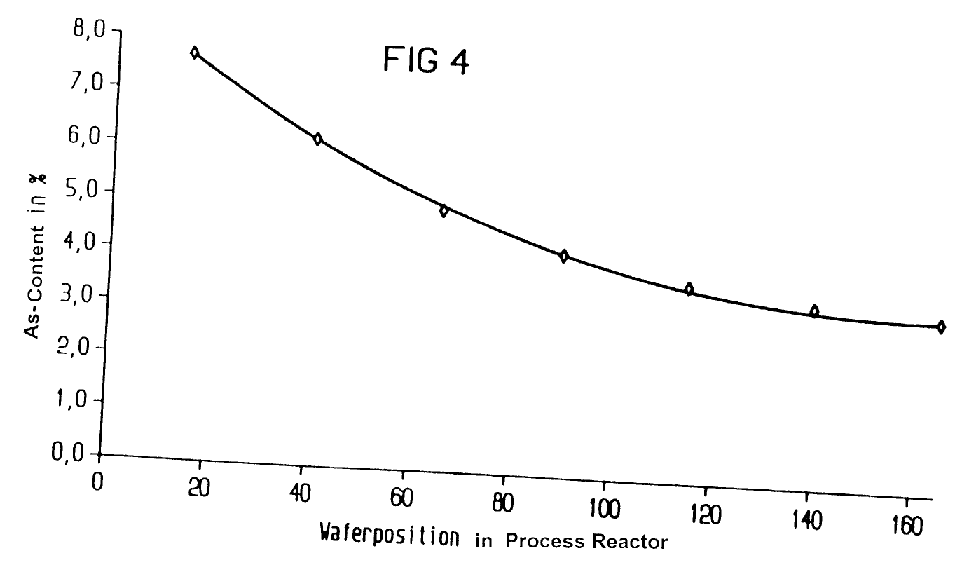

69. FIG. 4 is a graph in which an arsenic content is plotted against a wafer position in the process reactor; and

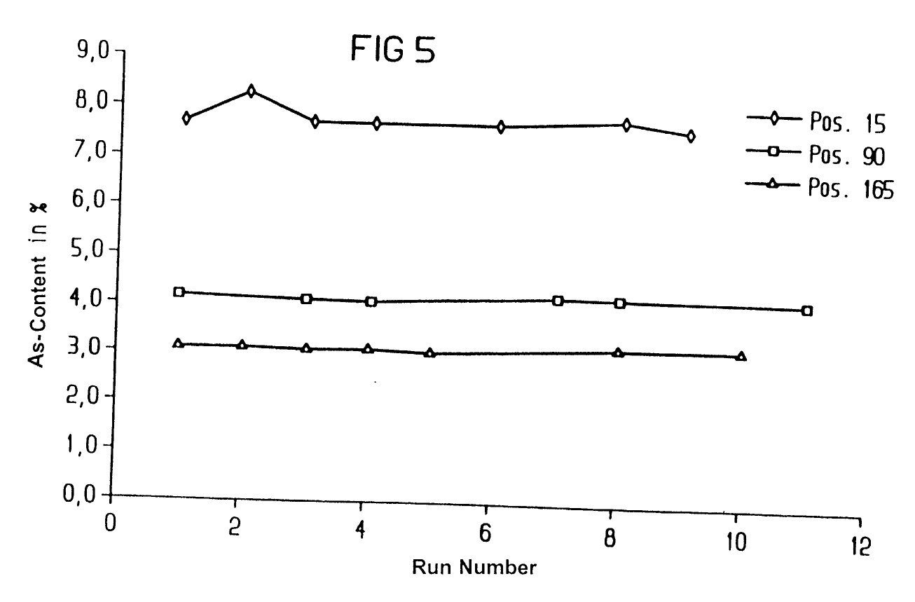

70. FIG. 5 is a graph in which the arsenic content is plotted against a number of process cycles in the process reactor.

### DESCRIPTION OF THE PREFERRED EMBODIMENTS

71. In all the figures of the drawing, sub-features and integral parts that correspond to one another bear the same reference symbol in each case. Referring now to the figures of the drawing in detail and first, particularly, to FIG. 1 thereof, there is shown a gas flow plan for a gas pipe system 30 according to the invention. The gas pipe system 30 is connected via gas inlet openings 16a and 16b to a process reactor 10, in the present exemplary embodiment to a vertical oven 10 for the treatment of wafers.

72. As can be seen from FIG. 1, the gas pipe system 30 has pipes of different thickness. The pipes represented by bold lines have a diameter of 12 mm and are composed of drawn or electrically polished stainless steel. These pipes are heated. The pipes represented by thin lines in FIG. 1 have a diameter of 6 mm, are likewise produced from drawn or electrically polished stainless steel, and are unheated in the present exemplary embodiment.

73. Either hand-operated valves (which are identified by the T-shaped symbol) or electropneumatic valves (which are identified by the square symbol) are used as valves. The sizes of the valves are matched to the respective pipe diameters.

74. The gas pipe system 30 is configured as stated below.

75. A TEOS evaporator 32 is connected to a helium gas source 26. Nitrogen may also be used, for example, instead of the helium. A TEOS tank 33 is provided between the TEOS evaporator 32 and the helium gas source 26. The helium is passed via pipes 62 and 64 into the TEOS tank 33. Valves 61 and 66 are provided in the pipes 62 and 64, in order to control the gas flow. Furthermore, a pipe 63 with a check valve 65 is provided at a junction point of the pipes 62 and 64. The pipe 63 leads to an exhaust-air output from the gas pipe system 30. The pipe 64 leads directly into the TEOS tank 33. A pipe 68 having a valve 67 leads from the output of the TEOS tank 33 to the TEOS evaporator 32. Upstream of the inlet into the TEOS evaporator 32, the pipe 68 opens into a heated pipe 71 with valves 70 and 69. On an output side, a heated pipe 36 with valves 72 and 73 leads away from the TEOS evaporator 32. The pipe 36 on the one hand opens into a valve 47, and on the other hand branches into a further heated pipe 37 with a valve 74, via which pipe 37 the TEOS evaporator 32 is connected to the gas inlet opening 16a of the vertical oven 10. A pressure sensor 75 is provided on the pipe 37, in order to check the pressure.

76. Furthermore, the gas pipe system 30 has a TEAS bubbler 31 that is connected to a carrier gas source 27. In the present exemplary embodiment, nitrogen is used as the carrier gas. Nitrogen is fed into the system via a valve 38, and flows via a pipe 48 to the TEAS bubbler 31. A mass flow controller 49, valves 50, 53, 54, a gas filter 51 and a check valve 52 are disposed in the pipe 48. The pipe 48 opens in the valve 54. A heated pipe piece 55 is provided, starting from the valve 54, and opens directly into the TEAS bubbler 31.

77. On the output side, a heated pipe 34 leads away from the TEAS bubbler 31, on the one hand ends in a valve 46 and on the other hand branches into a heated pipe 35, which is connected via a valve 60 to the gas inlet opening 16b of the vertical oven.

78. A bypass valve 58 is also provided between the pipes 48 and 43. In some cases, which will be described in more detail below, it is desirable for the nitrogen carrier gas not to be passed through the TEAS bubbler 31, for example in order to purge the pipes. To this end, further pipes 39 and 42 are provided downstream of the input valve 38, and respectively have a mass flow controller 40, 43 and a valve 41, 44. The two pipes 39 and 42 are joined together upstream of a gas filter 45, and continue as a single pipe 39. The pipe 39 opens via a branch into the valve 46, and is thus connected to the heated pipe 34 leading away from the TEAS bubbler 31. In its end region, the pipe 39 opens into the valve 47, so that it is also connected to the heated pipe 36 that leads away from the TEOS evaporator 32.

79. Finally, a pressure sensor 79 is also provided on the vertical oven, in order to monitor the process pressure, and is connected via a heated pipe 76 as well as valves 77, 78 to the vertical oven 10.

80. The method of operation of the gas pipe system 30 will now be described in the following text.

81. During the initial process and main process, the aim is to feed TEAS and TEOS into the vertical oven 10 in a defined ratio and state. To this end, the helium gas is first fed into the unheated TEOS tank 33 via the pipes 62 and 64. The purpose of the helium is to fill the TEOS evaporator 32 from the TEOS tank 33. The TEOS is fed into the TEOS evaporator 32 from the TEOS tank 33 via the pipes 68 and 71. The TEOS evaporator is at a temperature of 25 to 35° C. In this case, it is important that the temperature in the TEOS evaporator is constant, since this is necessary to ensure a constant TEOS vapor pressure. For this reason, the TEOS coming from the TEOS tank 33 is already preheated, via the heated pipe 71, before it enters the TEOS evaporator 32. The vaporized TEOS passes via the heated pipes 36 and 37 to the gas inlet opening 16a of the vertical oven 10. The valve 47 is closed in this phase of the method.

82. In order to allow accurately defined supply conditions for the TEOS into the vertical oven, the heated pipes 36, 37 have areas of different temperature. The temperature settings are produced via a four-channel pipeline heater (not shown). In the present exemplary embodiment, a total of four areas I, II, III and IV of different temperature are provided. In this case, it is necessary to ensure that the temperature profile in the heated pipes 36, 37 rises from the TEOS evaporator 32 toward the vertical oven 10. The first area I, that is directly adjacent to the output of the TEOS evaporator 32, is at a temperature which is 2° C. higher than the temperature in the TEOS evaporator 32. The temperature is then raised by 2° C. in each of the subsequent areas II, III and IV, so that the TEOS enters the vertical oven 10 at a temperature which is 8° C. higher than the temperature in the TEOS evaporator 32.

83. In order to feed TEAS into the vertical oven 10, the nitrogen carrier gas is first fed into the TEAS bubbler 31. To do this, the valves 41 and 44 are closed, so that the nitrogen flows through the pipe 48. In the process, the gas passes the mass flow controller 49, by which the gas flow can be adjusted in the range from 0 to 200 standard cubic centimeters per minute (sccm). Since the bypass valve 58 is closed, the nitrogen finally passes via the heated pipe section 55 into the TEAS bubbler 31. The temperature in the bubbler is 30 to 50° C., and this must once again be kept constant since a constant temperature in the TEAS bubbler 31 is important for the saturation level of the carrier gas. The TEAS with the carrier gas is fed into the vertical oven 10 via the heated pipes 34 and 35. In this case, the valve 46 is closed. In a similar way to the TEOS evaporator 32, the pipes 34, 35 also have areas of different temperature, which are set via a four-channel pipeline heater. Once again, four areas I, II, III and IV are provided, in each of which the temperature of the TEAS emerging from the TEAS bubbler 31 is raised by 2° C. toward the vertical oven. Finally, the TEAS is fed into the vertical oven via the gas inlet opening 16b.

84. The pressure in the heated pipes 34, 35 and 36, 37 is monitored via the pressure sensors 59 and 75.

85. Before or after the main process, it may be desirable for the vertical oven 10 to be purged in the standby mode, or else for the evacuated vertical oven to be ventilated. Both are carried out using the nitrogen carrier gas.

86. In order to purge the vertical oven 10, the valve 50 is closed and the valve 41 is opened, so that the nitrogen can flow into the pipe 39 via the mass flow controller 40. In this case, the mass flow controller 40 can be adjusted infinitely variably in the range from 0 to 2 standard liters per minute.

87. In the area of the branch upstream of the valve 46, which is open, the nitrogen gas flow is split into equal parts so that, when the valve 47 is opened, the heated pipes 35, part of 34, 37 and part of 36 are purged by nitrogen. The TEOS and TEAS pipes may also be purged successively, of course, by appropriate valve settings. The function of the gas filter provided in the pipe 39 is, in particular, to protect the heated pipes and the wafers from contamination.

88. When the evacuated vertical oven 10 is ventilated at atmospheric pressure, the valve 44 and the mass flow controller 43 are also actuated, in addition, for the purpose of purging. The mass flow controller can be adjusted infinitely variably in a range from 0 to 10 standard liters per minute. This additional actuation results in the increased gas flow required for ventilation.

89. Before changing the TEAS source, it is normally necessary for the heated TEAS pipes 34 and 35 to be purged. This is achieved as follows: since the TEAS bubbler 31 must be unscrewed above the valves 54 and 56 in order to change the TEAS source, these valves must first be closed. At the same time, the bypass valve 58 must be opened. When the valves 41, 44 are closed and the valve 50 is open, nitrogen flows through the pipe 48 and via the bypass valve 58 and the open valve 57 into the heated pipes 34 and 35, as a result of which they are purged.

90. Finally, it is necessary to refill the TEOS evaporator 32 after each process run, in order to ensure a constant filling level. In order to refill the TEOS evaporator 32, it is important that the helium is used with a filling pressure of less than 10 PSI. The helium forces the liquid TEOS out of the TEOS tank 33 into the pipe 68 where, first, it meets the closed valve 70. When the valve 70 is opened, the filling process starts. The filling process is stopped automatically by closing the valve 70, depending on a time set in a control program or depending on a filling level sensor. If, for example due to a malfunction, a helium pressure of more than 10 PSI occurs, then the excess pressure is dissipated via the check valve 65. This protects the gas pipe system 30 against excessively high gas pressure, and prevents uncontrolled filling.

91. FIG. 2 shows, in highly simplified form, an exemplary embodiment of the process reactor according to the invention, in the form of the vertical oven 10. The vertical oven 10 contains an oven housing 11, which is provided with a heating cartridge 24 on the inside. A 5-zone heating cartridge may be used, for example, here. A process tube 12 is provided inside the heating cartridge 24, and is detachably connected to a flange 15. A tubular or cylindrical liner 13 is also provided inside the process tube 12 and is used to screen a boot (holding apparatus) 14 for accommodating a large number of wafers 19. The walls of the process tube 12, of the liner 13 and of the boot (holding apparatus) 14 form a flow channel 18. Both the boot (holding apparatus) 14 and the liner 13 are detachably connected to the flange 15. The flange 15 has a gas inlet 16 and a gas outlet 17.

92. As can also be seen in FIG. 3, the flange 15 in each case has the gas inlet opening 16a and the gas inlet opening 16b as the gas inlet, via which openings the vertical oven 10 can be connected to the gas pipe system 30 described above and as shown in FIG. 1. Furthermore, the flange 15 has connections 20, 21 for a heating/cooling apparatus (not shown), via which the flange 15 can be heated. A row of supporting legs 22 and supporting feet 23 are provided in order to support the flange 15 securely and firmly, and thus to support the vertical oven 10 on the base.

93. The operation of the vertical oven 10 and the implementation of the TEAS method will now be described with reference to FIGS. 2 and 3 as well as 4 and 5.

94. Using the TEAS method, the aim is to deposit As-doped SiO₂ layers onto wafers by a gas-phase deposition in each case. A range of parameters must be satisfied in order to achieve a stable layer thickness of 150 nm on the wafers and in order to ensure that each of the deposited layers has an arsenic content of 5.5%±2.5%. First, a suitable temperature and a suitable pressure must be set in the vertical oven 10. Furthermore, the flange temperature must be set appropriately. Finally, the vertical oven 10 must be supplied with a defined TEOS/TEAS ratio.

95. In order to achieve suitable deposition of As-doped SiO₂ layers on the wafers 19, the boot (holding apparatus) 14 is first fitted with a large number of wafers 19. In the present exemplary embodiment, the boot (holding apparatus) 14 of the vertical oven 10 is fitted with a total of 166 wafers 19, of which 150 wafers are productive wafers.

96. The oven interior is then heated within the process tube 12 to a temperature of 600 to 700° C. At the same time, the pressure in the process tube 12 is set to a value of 66.6± 13.3 Pa. This low pressure results in a concentration gradient that is sufficiently low that the concentration of reaction gases is virtually the same at every point on the wafer surfaces during the process. The flange 15 is then heated via the heating/cooling system, with the medium located in the heating/cooling system being brought to a temperature of more than 90° C. This prevents undefined deposition of the process gases on the flange 15. Finally, TEAS and TEOS are supplied in the manner described above from the gas pipe system 30, via the gas inlet openings 16a and 16b. The gas flowing in flows upward in the flow channel 18, which is formed by the liner 13 and the boot (holding apparatus) 14, with the gas also passing around the wafers 19. The corresponding gas reactions lead to the desired deposits on the wafers 19. At the free end of the flow channel 18, the gas flow is deflected and is passed back in the direction of the flange 15 again, via that part of the flow channel 18 which is formed by the liner 13 and the process tube 12. The flange 15 has the gas outlet 17, through which the reaction gas is carried away outward. FIG. 2 uses arrows to show how the gas flows.

97. This method results in layers being deposited on the wafers 19 which completely satisfy the preconditions mentioned above, in particular with respect to layer thickness stability and arsenic content.

98. FIGS. 4 and 5 show examples of results achieved using the TEAS method on the vertical oven 10.

99. FIG. 4 is a graph showing the arsenic content plotted against the corresponding wafer position in the process reactor—in this case the vertical oven 10. The wafer position 0 is in this case located in the vicinity of the gas inlet 16 (FIG. 2), while the position 166 is the wafer position located furthest away from the gas inlet 16. As the curve profile in FIG. 4 shows, the precondition that the arsenic content in the deposited layers should vary in a range from 5.5%±2.5% is satisfied in all areas of the vertical oven, and over its entire length.

100. FIG. 5 is a graph in which the arsenic content in the deposited layers is plotted against the run number. In this case, the following sequence is called a run: fitting 166 wafers 19 into the vertical oven 10, carrying out the TEAS method, unloading the processed wafers from the vertical oven 10, and measuring the process results. FIG. 5 shows a total of three curves, with each curve having been determined for a specific wafer position in the vertical oven 10. The curve marked by diamonds was determined at the wafer position 15, and thus in the vicinity of the gas inlet. The curve marked by squares was recorded at wafer position 90, and thus in the center of the vertical oven. Finally, the curve marked by triangles was determined for the wafer position 165. This position corresponds to the position in the vertical oven located furthest away from the gas inlet.

101. As is evident from the curves in FIG. 5, the arsenic content in up to ten runs is essentially constant at all positions in the vertical oven 10, so that the method according to the invention is suitable for producing stable arsenic contents even over a relatively long time period. In this case, it is worth noting that the arsenic contents scarcely vary even during subsequent process runs. This is a particular improvement with respect to the systems known from the prior art. Furthermore, FIG. 5 also clearly shows once again that the arsenic content is in the required range for optimum arsenic deposition over the entire length of the vertical oven.

We claim:

1. A method for depositing an As-doped SiO₂ layer on semiconductor substrates, which comprises:
fitting a process reactor having a process tube and a flange, with a large number of the semiconductor substrates to be treated, the semiconductor substrates being introduced into the process tube;
heating the process reactor to a temperature of 450 to 1250° C.;
heating the flange via a heating/cooling apparatus disposed on the flange, the heating/cooling apparatus containing a medium which is at a temperature of more than 90° C.;
introducing tetraethylorthosilicate (TEOS) and triethylarsenate (TEAS) into the process reactor in order to deposit the As-doped SiO₂ layer, with the TEAS being introduced via at least one first heated pipe from a first evaporator containing liquid TEAS, and the TEOS being introduced via at least one second heated pipe from a second evaporator containing liquid TEAS; and
depositing the As-doped SiO₂ layer on the semiconductor substrates.

2. The method according to claim 1, which comprises setting a pressure in the process reactor between 20 to 100 Pa.

3. The method according to claim 1, which comprises setting the liquid TEAS in the first evaporator to a constant temperature of between 25° C. and 90° C. with an accuracy of ±0.5° C.

4. The method according to claim 1, which comprises setting the liquid TEOS in the second evaporator to a constant temperature of between 25° C. and 90° C. with an accuracy of ± 0.5° C.

5. The method according to claim 1, which comprises setting a TEOS flow via a TEOS vaporization temperature in the second evaporator.

6. The method according to claim 1, which comprise vaporizing the TEAS by blowing an inert gas through the liquid TEAS in the first evaporator.

7. The method according to claim 2, which comprises adjusting a TEAS flow via a temperature in the first evaporator and a flow of a carrier gas.

8. The method according to claim 7, which comprises providing the flow of the carrier gas at 50 to 200 standard cubic centimeters per minute (sccm).

9. The method according to claim 1, which comprises matching a deposition time, the temperature and a pressure in the process reactor, a vaporization rate of the TEAS and the TEOS as well as a TEAS/TEOS ratio to one another such that the As-doped SiO₂ layer with a thickness of approximately 150 nm is deposited.

10. The method according to claim 1, which comprises providing the As-doped SiO₂ layer with an arsenic content of 5.5%±2.5%.

11. The method according to claim 1, which comprises heating the process reactor to the temperature of between 600 to 700° C.

12. The method according to claim 2, which comprises setting the pressure in the process reactor to 66.6±13.3 Pa.

13. The method according to claim 1, which comprises setting the liquid TEAS in the first evaporator to a constant temperature of between 30° C. and 50° C. with an accuracy of ±0.5° C.

14. The method according to claim 1, which comprises setting the liquid TEOS in the second evaporator to a constant temperature of between 25° C. and 35° C. with an accuracy of ± 0.5° C.

15. The method according to claim 1, which comprises vaporizing the TEAS by blowing nitrogen gas through the liquid TEAS in the first evaporator.
